(19) United States
(12) Patent Application Publication
(10) Pub. No.: US 2024/0006824 A1
(43) Pub. Date: Jan. 4, 2024

(54) Device For Detecting The Temperature Of An Electric Coupling Element, And Method

(71) Applicant: Lisa Dräxlmaier GmbH, Vilsbiburg (DE)

(72) Inventors: Uros Livk, Garching (DE); Stephan Heckelsmüller, Eching (DE); Thomas Weng, Neufahrn (DE); Stephan Schaffer-Hans, Munchen (DE)

(21) Appl. No.: 17/922,389

(22) PCT Filed: Apr. 28, 2021
(86) PCT No.: PCT/EP2021/061042

§ 371 Date: Sep. 17, 2023

(30) Foreign Application Priority Data
Apr. 29, 2020 (DE) 10 2020 111 641.1

(51) Int. Cl. H01R 13/66; H05K 1/02; B60L 53/16

(52) U.S. Cl. CPC H01R 13/6683; H05K 1/0201; B60L 53/16; H01R 2201/26; H05K 2201/10151

(57) ABSTRACT

This disclosure relates to a device for detecting the temperature of an electric coupling element. The device includes an electric contact element which is designed to conduct an electric current to an electric component. A component support is also included and arranged on the contact element and includes a thermally conductive region in direct contact with the contact element. The component support is equipped with a printed circuit board which includes at least one temperature sensor that detects the temperature of the electric coupling element.

### CROSS REFERENCE TO RELATED APPLICATIONS

This application is a United States National Phase of International Patent Application PCT/EP2021/061042, filed on Apr. 28, 2021, which claims priority to German Patent Application DE 102020111641.1, filed Apr. 29, 2020, the content of both of which are herein incorporated by reference.

### BACKGROUND OF THE INVENTION

### Field of the Invention

The present invention relates to an apparatus for detecting a temperature of an electrical coupling element. Furthermore, the invention relates to a method for detecting a temperature of an electrical coupling element.

### Description of Related Art

During an electrical charging process of an electric vehicle, current and voltage transmission generate thermal energy within an electrical coupling element such as a charging socket and a charging plug. The heat energy generated during the current flow can cause the charging socket and the charging plug to overheat. To ensure safe operation of the electrical charging process, the temperature of the current-carrying and voltage-carrying elements of the charging socket and charging plug are measured. This can be done by means of a temperature sensor connected to the current-carrying and voltage-carrying elements via a cable. This requires a great deal of installation work and a long heat conduction path. The temperature can also be measured using temperature sensors mounted on a printed circuit board.

DE 10 2019 114 229 A1 relates to a charging plug, in particular for an electric vehicle, wherein the charging plug comprises a circuit on a printed circuit board, a component carrier and at least one contact element aligned transversely to the printed circuit board, wherein the circuit for the contact element comprises a temperature sensor and the component carrier consists of an electrically insulating, thermally conductive material, the temperature sensor being arranged on a front side of the printed circuit board, which is aligned transversely with respect to the contact element, in an edge region of the printed circuit board, and the component support being arranged as an electrical insulator and heat conductor between the contact element and the temperature sensor, the component support bearing against the contact element at least in the region of the temperature sensor, and the temperature sensor being arranged in a depression in the component support.

### BRIEF SUMMARY OF THE INVENTION

It is therefore an object of the invention to perform an efficient temperature measurement of electrical current- and voltage-carrying components during an electrical charging process by using means that are as simple as possible in terms of design.

One aspect of the invention relates to an apparatus for sensing a temperature of an electrical coupling element comprising an electrical contact element adapted to carry electrical current to an electrical component and a component support disposed on the contact element, the component support comprising a thermally conductive region in direct contact with the contact element, wherein a circuit board is disposed on the component support, the circuit board comprising at least one temperature sensor that senses the temperature of the contact element and thus the electrical coupling element.

The electrical coupling element can be a charging socket or a charging plug, which are required for an electrical charging process, in particular for an electric vehicle. To electrically charge the electric vehicle, the electrical coupling element, for example the charging socket, is coupled to another electrical coupling element, for example the charging plug. The contact element is, for example, a high-voltage pin, which is located inside the electrical coupling element. The contact element may in particular be made of a metal material. The electrical coupling element may have several contact elements. During electrical charging, high electrical voltages and charging currents flow in the contact element.

The component carrier is arranged on the contact element and comprises a thermally conductive region in direct contact with the contact element. The component support preferably comprises a hard component, for example a thermoplastic, and the thermally conductive region as a soft component. The thermally conductive area, as soft component, is used for the directional heat transport from the contact element to the temperature sensor. The hard component is required to facilitate assembly with a high degree of automation. In addition, the geometry of the hard component is shaped in such a way that the required minimum values for the clearance and creepage distances between the contact element and the temperature sensor are exceeded. The hard component has a very low thermal conductivity (e.g., 0, 15 W/(m*K), so that the heat flow to the surrounding air and adjacent components is minimized. The component carrier can be screwed to the contact element. The thermally conductive area provides galvanic isolation between the contact element and the temperature sensor. The hot current of the contact element is conducted via the thermally conductive area to the temperature sensor. For example, an elastomer can be designed as the thermally conductive area. Likewise, the thermally conductive area may have ceramic or mineral elements that provide higher thermal conductivity of the thermally conductive area. For example, the thermally conductive area can achieve a thermal conductivity of 1.5 W/(m*K). It should be noted, however, that too high a degree of thermal conductivity can cause the elastomer to become hard and less able to conform to the contact element and the printed circuit board. A compromise must therefore be made between thermal conductivity and hardness for the thermally conductive area.

The component carrier can comprise a further area which consists of a hard component, for example a thermoplastic. This area can be subjected to mechanical stress and is used to facilitate mounting of the component carrier on the contact element. Depending on the manufacturing and assembly process, the mechanical requirements of the component carrier may vary. In addition, the further area achieves only a low thermal conductivity, whereby the heat flow passes through the thermally conductive area to the temperature sensor. The component carrier is shaped to provide clearance and creepage distances for high-voltage/low-voltage isolation. For this purpose, a collar is provided which runs parallel to the surface of the contact element and electrically insulates it from the printed circuit board. The temperature sensor is placed on the side of the circuit board facing away from the component carrier to protect it from mechanical stress.

The printed circuit board is arranged on the component carrier. The printed circuit board can be attached to the component carrier by means of clip elements. The printed circuit board can be referred to as a PCB. The temperature sensor is arranged on the PCB, which is arranged as close as possible to the thermally conductive area and the contact element. The temperature sensor may be soldered to the PCB. The temperature sensor can be operated at a low voltage level, for example up to 12 volts. The direct arrangement of the temperature sensor on the thermally conductive area results in a lower heat loss, which ensures accuracy of the detected values of the temperature sensor.

The temperature sensor can detect a value of a temperature of the electrical coupling element and map it in an electrical signal. The temperature sensor is electrically isolated from the contact element and is arranged outside a high-voltage area of the contact element.

The device may comprise a housing which is formed in several parts. The housing can be made of an electrically insulating material. The housing can have receptacles for several contact elements. The contact element may be press-fitted in a rear housing element. Between the rear housing element and a front housing element, the component carrier, the printed circuit board and the temperature sensor may be arranged, which are enclosed within the housing when the housing is assembled. For example, the housing may be plugged together.

An elastic sealing mat can be arranged between a front housing element and the circuit board. The sealing mat can have a nose in the area of the temperature sensor. The nose can serve as a stop surface for the printed circuit board. The nose can also be elastic. The lug can compensate for component tolerances. The contact element can be fixed in a rear housing element. For example, the contact element can be pressed into the rear housing element. The front housing member and the rear housing member may be joined together to enclose the component carrier with the printed circuit board in an interior of the housing.

Furthermore, a thermally conductive paste can be inserted between the contact element and the component carrier and/or between the component carrier and the printed circuit board to increase the thermal conductivity. The temperature sensor can be thermally coupled to the printed circuit board and the component carrier using the thermally conductive material. Increased thermal conductivity ensures accuracy of the recorded temperature values.

In a preferred embodiment, the printed circuit board comprises thermally conductive elements for increasing the thermal conductivity of the printed circuit board. For example, copper elements can be embedded in the printed circuit board as heat-conducting elements. For this purpose, elements with high thermal conductivity are embedded in the printed circuit board, for example thermal vias made of copper, especially in the area of the temperature sensor. The printed circuit board can include the thermally conductive elements directly at the temperature sensor.

It is further provided that at least one further printed circuit board is arranged on the component carrier, which comprises at least one further temperature sensor. By means of further printed circuit boards and temperature sensors, the temperature of the contact element can be detected at the contact element at several measuring points. Furthermore, a thermally conductive paste is applied to increase the thermal conductivity between the contact element and the component carrier and/or between the component carrier and the printed circuit board. The thermally conductive paste can be elastic or plastically deformable.

In a further embodiment, the arrangement of the component carrier on the contact element comprises injection molding with a plastic on the contact element. The component carrier can thus be injection molded directly onto the contact element. This allows a high degree of automation in the assembly of the electrical coupling element.

Furthermore, at least one further printed circuit board is arranged on the component carrier, which comprises at least one further temperature sensor.

### BRIEF DESCRIPTION OF THE SEVERAL VIEWS OF THE DRAWINGS

Further advantages, features, and details of the various embodiments of this disclosure will become apparent from the ensuing description of a preferred exemplary embodiment and with the aid of the drawings. The features and combinations of features recited below in the description, as well as the features and feature combination shown after that in the drawing description or in the drawings alone, may be used not only in the particular combination recited, but also in other combinations on their own, without departing from the scope of the disclosure.

An advantageous embodiment of the present invention is set out below with reference to the accompanying figures, wherein:

FIG. 1 depicts a sectional view of the electrical contact element according to a first example,

FIG. 2 depicts a sectional view through the electrical contact element according to a second example, and

FIG. 3 depicts a sectional view of the electrical contact element according to a third example.

### DETAILED DESCRIPTION OF THE INVENTION

As used throughout the present disclosure, unless specifically stated otherwise, the term “or” encompasses all possible combinations, except where infeasible. For example, the expression “A or B” shall mean A alone, B alone, or A and B together. If it is stated that a component includes “A, B, or C”, then, unless specifically stated otherwise or infeasible, the component may include A, or B, or C, or A and B, or A and C, or B and C, or A and B and C. Expressions such as “at least one of” do not necessarily modify an entirety of the following list and do not necessarily modify each member of the list, such that “at least one of “A, B, and C” should not be understood as including only one of A, only one of B, only one of C, or any combination of A, B, and C.

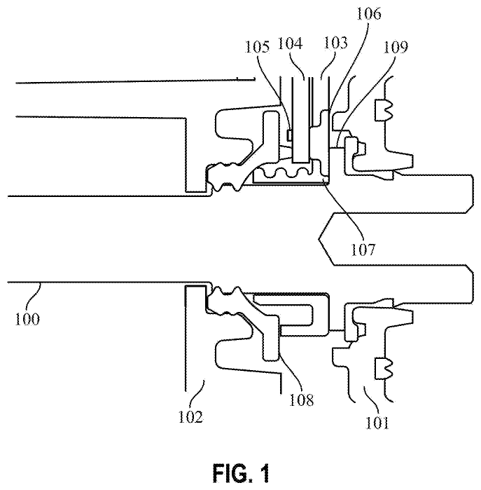

FIG. 1 depicts a sectional view through the electrical contact element 100 according to an example first embodiment.

The electrical contact element 100 is part of an electrical coupling element. For example, the electrical coupling element may be a charging plug or a charging socket, in particular for an electric vehicle. In the first embodiment, the electrical contact element 100 is a pin 100. The pin 100 is inserted into a rear housing element 101 of a two-piece housing and is mechanically connected to the rear housing element 101. The rear housing element 101 can be connected to a front housing element 102, for example, by means of screwing, clipping or welded to each other. A component carrier 103 and a printed circuit board 104 are disposed between the rear housing member 101 and a front housing member 102.

The circuit board 104 abuts the component support 103 and is attached to the component support 103. The printed circuit board 104 comprises a temperature sensor 105 on a side of the printed circuit board 104 opposite the component carrier 103. The temperature sensor 105 is used to detect the temperature of the electronic component, in particular the pin 100.

Further, the component carrier 103 includes a thermally conductive region 106. The temperature sensor 105 is disposed as close as possible to a contact point between the pin 100 and the thermally conductive region 106. The thermally conductive region 106 may consist of a thermally conductive elastomer. A heat flow of the pin 100 thus conducts via the thermally conductive area 106 of the component carrier 103 via the printed circuit board 104 to the temperature sensor 105. To increase the thermal conductivity of the printed circuit board 104, the printed circuit board 104 can have thermally conductive elements in an area of the temperature sensor 105.

The component carrier 103 isolates the temperature sensor 105 from the high voltage applied to the pin 100 during operation. In addition to the thermally conductive region 106, the component support 103 includes a hard component region 107 that has a low thermal conductivity. The hard component region 107 may, for example, includes a thermal conductivity of 0.15 W/(m*K). In addition, the hard component area 107 can be subjected to mechanical stress.

The component carrier 103 is to be arranged on a protrusion 109 of the contact element 100 in such a way that the thermally conductive region 106 is in direct contact with the protrusion 109 of the contact element 100. As a result, the hot current conducts directly from the contact element 100 through the thermally conductive region 106 to the temperature sensor 105.

A resilient sealing mat 108 is disposed on the pin 100, for example, to provide a fluid-tight seal to the pin 100. The sealing mat 108 is inserted into the front housing element 102.

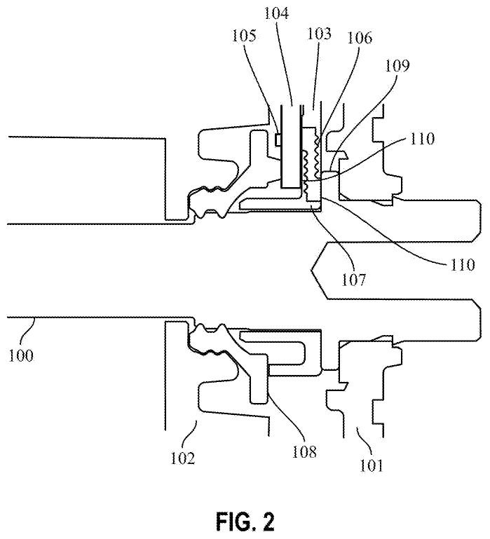

FIG. 2 depicts a sectional view through the electrical contact element 100 according to a second embodiment.

According to the second embodiment example, the hard component region 107 is made of a thermoplastic. The thermally conductive area 106 is made of ceramic. The ceramic has structural-mechanical properties with the thermoplastic, so that the mechanical stressability and the thermal conductivity are ensured. A thermally conductive paste 110 is applied between the pin 100 and the component carrier 103, and between the component carrier 103 and the printed circuit board 104. According to another embodiment, the thermally conductive paste 110 is applied between the component carrier 103 and the printed circuit board 104 or between the pin 100 and the component carrier 103.

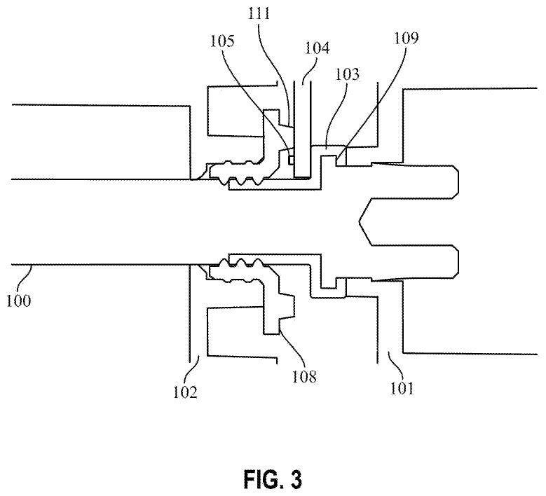

FIG. 3 depicts a sectional view through the electrical contact element 100 according to a third embodiment.

According to the third embodiment, the component carrier 103 is overmolded around the pin 100. The component carrier 103 is made of a plastic, in particular an elastomer. The elastomer is molded onto a projection 109 of the pin 100 in an area between the front housing member 102 and the rear housing member 101. The printed circuit board 104 directly abuts the component support 103 and is attached to the component support 103, for example, via clip elements. The elastic sealing mat 108 comprises a lug 111 on the side facing the temperature sensor 105. The lug 111 lies against the flat of the printed circuit board 104 arranged on the temperature sensor 105 and protects the temperature sensor 105 from mechanical stresses, in particular when the front housing element 102 is joined to the rear housing element 101. Furthermore, the lug 111 can compensate for component tolerances. The lug 111 may also be resilient.

For assembly, the pin 100 is fixed into the rear housing element 101. For example, the pin 100 can be pressed into the rear housing element 101. Thermal conductive paste 110 may be applied to the component support 103. Alternatively, the hot conductive paste 110 can also be applied to the contact element 100. The printed circuit board 104 is then attached to the surface of the component carrier 103 which has been applied with hot conductive paste 110. The sealing mat 108 is arranged on the front housing element 102. The front housing element 102 is pushed over the pin 100 and thus the component carrier 103 with the printed circuit board 104 is pressed against the pin 100 at the same time.

The approach presented here features a low-cost and simple architecture. By thermally coupling the temperature sensor with the contact element via the PCB and the thermally conductive area of the component carrier, temperature sensing is simplified and increased measurement accuracy can be ensured. The component carrier can be manufactured as an injection-molded plastic part and molded directly onto the contact element. The assembly of the electrical coupling element can be automated by a plug-in assembly.

Since the devices and methods described in detail above are examples of embodiments, they can be modified to a wide extent by the skilled person in the usual manner without leaving the scope of the invention. In particular, the mechanical arrangements and the proportions of the individual elements with respect to each other are merely exemplary. Some preferred embodiments of apparatus according to the invention have been disclosed above. The invention is not limited to the solutions explained above, but the innovative solutions can be applied in different ways within the limits set by the claims.

1. Device for sensing a temperature of an electrical coupling element comprising an electrical contact element (100) adapted to conduct electrical current to an electrical component;
a component support (103) which can be arranged on the contact element (100),
the component support (103) comprises a thermally conductive region (106) in direct contact with the contact element (100), a printed circuit board (104) being arranged on the component support (103), which printed circuit board (104) comprises at least one temperature sensor (105) which senses the temperature of the contact element (100) and thus of the electrical coupling element.

2. Device according to claim 1, characterized in that the printed circuit board (104) is arranged directly on the thermally conductive region (106) and the temperature sensor (105) is arranged on the side of the printed circuit board (104) facing away from the thermally conductive region (106).

3. Device according to one of the claim 1 or 2, characterized in that a thermally conductive paste (110) for increasing the thermal conductivity can be introduced between contact element (100) and component carrier (103) and/or between component carrier (103) and printed circuit board (104).

4. Device according to any of the preceding claims, wherein the printed circuit board (104) comprises thermally conductive elements for increasing the thermal conductivity of the printed circuit board (104).

5. Device according to one of the preceding claims, characterized in that at least one further printed circuit board (104) is arranged on the component carrier (103), which printed circuit board (104) comprises at least one further temperature sensor (105).

6. Method for detecting a temperature of an electrical coupling element, comprising providing an electrical contact element (100) which is arranged to conduct electrical current to an electrical component,
disposing a component support (103) on the contact element (100), the component support (103) comprising a thermally conductive region (106) in direct contact with the contact element (100), and
arranging the printed circuit board (104) on the component carrier (103), which comprises at least one temperature sensor (105), the temperature of the contact element (100) and thus of the electrical coupling element being detected by the temperature sensor (105).

7. Method according to claim 6, characterized in that the temperature is measured on the side of the printed circuit board (104) facing away from the thermally conductive region (106).

8. Method according to one of claim 6 or 7, characterized in that a thermally conductive paste (110) for increasing the thermal conductivity is introduced between contact element (100) and component carrier (103) and/or between component carrier (103) and printed circuit board (104).

9. Method according to any one of claims 6 to 8, wherein arranging the component carrier (103) on the contact element (100) comprises injection molding with a plastic on the contact element (100).

10. Method according to any one of claims 6 to 9, characterized in that at least one further printed circuit board (104) comprising at least one further temperature sensor (105) is arranged on the component carrier (103).
